(19) United States
(12) Patent Application Publication
(10) Pub. No.: US 2022/0295600 A1
(43) Pub. Date: Sep. 15, 2022

(54) SENSOR COVER HEAT GENERATING STRUCTURE

(71) Applicant: TOYODA GOSEI CO., LTD., Kiyosu-shi (JP)

(72) Inventor: Koji FUKAGAWA, Kiyosu-shi (JP)

(21) Appl. No.: 17/686,884

(22) Filed: Mar. 4, 2022

(30) Foreign Application Priority Data
Mar. 9, 2021 (JP) 2021-036862

(51) Int. Cl. H05B 3/16; G01S 7/02

(52) U.S. Cl. CPC H05B 3/16; G01S 7/027; H05B 2203/011

(57) ABSTRACT

A sensor cover heat generating structure, applied to a sensor cover of an in-vehicle sensor that transmits and receives an electromagnetic wave for detecting an object outside a vehicle, the sensor cover being located in front of the in-vehicle sensor in a transmission direction of the electromagnetic wave, the heat generating structure includes: a heater wire provided to the sensor cover, the heater wire being configured to generate heat when the heater wire is energized. The heater wire includes two electrode portions and a plurality of parallel portions, the two electrode portions have a predetermined length and are disposed at a distance from each other, the plurality of parallel portions extend in parallel to each other so as to connect the two electrode portions, and the electrode portions have a wire width equal to or greater than a total value of wire widths of the plurality of parallel portions.

### CROSS-REFERENCE TO RELATED APPLICATION(S)

This application is based upon and claims the benefit of priority from prior Japanese patent application No. 2021-036862 filed on Mar. 9, 2021, the entire contents of which are incorporated herein by reference.

### BACKGROUND

### 1. Field of the Invention

The present invention relates to a sensor cover heat generating structure.

### 2. Description of the Related Art

A vehicle such as an automobile is equipped with an in-vehicle sensor that transmits and receives an electromagnetic wave for detecting an object outside the vehicle. A sensor cover is provided in front of the in-vehicle sensor in a transmission direction of the electromagnetic wave. The sensor cover makes the in-vehicle sensor less visible from the outside of the vehicle. The sensor cover is capable of transmitting electromagnetic wave. However, transmittance of electromagnetic wave in the sensor cover decreases as ice and snow adhere to the sensor cover. For this reason, it is conceivable to provide the sensor cover with a heater wire as disclosed in JP-A-2019-145498. In this case, when the heater wire is energized to generate heat, ice and snow adhering to the sensor cover are melted. As a result, it is possible to limit a decrease in the transmittance of electromagnetic wave of the sensor cover due to adhesion of ice and snow.

In JP-A-2019-145498, one heater wire extends long over an entire portion to be heated of the sensor cover.

Here, a heat generation amount of the heater wire at a time of energization is determined by a resistance value R of the heater wire. The resistance value R of the heater wire is determined by the following equation “R=ρ·L/S” based on a specific resistance p, a length L, and a cross-sectional area S of the heater wire. As can be seen from this equation, since the resistance value R increases as the length L of the heater wire increases, the cross-sectional area S of a heater wire having a large length L needs to be increased in order to limit the heat generation amount of the heater wire to a desired value.

When the heater wire has a thin film shape, the cross-sectional area S of the heater wire is a product of a wire width w and a thickness t. Therefore, the above equation becomes “R=ρ·L/(w·t)”. In this case, it is understood that at least one of the wire width w and the thickness t of the heater wire needs to be increased in order to limit the heat generation amount of a heater wire having a large length L to a desired value. However, if the wire width w of the heater wire is too large, the transmittance of electromagnetic wave in the sensor cover is reduced due to the heater wire.

When the heater wire has a thin film shape, the wire width w cannot be set to be equal to or greater than a maximum value that can secure the transmittance of electromagnetic wave in the sensor cover. Accordingly, the thickness t of the heater wire needs to be increased in order to limit an increase in the heat generation amount of the heater wire due to an increase in the length L. Therefore, it is difficult to adopt a method that cannot sufficiently reduced the thickness t of the heater wire, such as sputtering, as a method for providing the heater wire to the sensor cover.

### SUMMARY

According to an aspect of the invention, there is provided a sensor cover heat generating structure, applied to a sensor cover of an in-vehicle sensor that transmits and receives an electromagnetic wave for detecting an object outside a vehicle, the sensor cover being located in front of the in-vehicle sensor in a transmission direction of the electromagnetic wave, the sensor cover heat generating structure including: a heater wire provided to the sensor cover, the heater wire being configured to generate heat when the heater wire is energized, where: the heater wire includes two electrode portions and a plurality of parallel portions; the two electrode portions have a predetermined length and are disposed at a distance from each other; the plurality of parallel portions extend in parallel to each other so as to connect the two electrode portions; and the electrode portions have a wire width equal to or greater than a total value of wire widths of the plurality of parallel portions.

According to the above configuration, a combined resistance value of the plurality of parallel portions can be limited small even if a resistance value of each of the parallel portions among the plurality of parallel portions is large. Therefore, in the case where the heater wire is formed in a thin film shape, when the wire width of the parallel portions of the heater wire is set to be less than the maximum value that can secure the transmittance of the electromagnetic wave in the sensor cover, the combined resistance value of the plurality of parallel portions can be limited small even if the thickness of the parallel portion is small. Accordingly, it is not necessary to increase the thickness of the parallel portions in order to limit the resistance value of the heater wire, that is, the heat generation amount of the heater wire, to a desired value. As a result, it is possible to adopt a method that cannot sufficiently reduced the thickness t of the heater wire, such as sputtering, as a method for providing the heater wire to the sensor cover, so that limitation on the method for providing the heater wire to the sensor cover can be prevented.

Since the wire width of the electrode portions is equal to or greater than the total value of the wire widths of the plurality of parallel portions, a current density of the electrode portions to which the plurality of parallel portions are connected can be limited small. As a result, it is possible to limit an increase in heat generation amount of the electrode portions, thereby limiting occurrence of uneven heat generation in the heater wire including the electrode portions and the plurality of parallel portions due to an increase in the heat generation amount of the electrode portions.

In the sensor cover heat generating structure according to the aspect, the electrode portions may be disposed at positions without interfering with the electromagnetic wave transmitted from the in-vehicle sensor.

The wire width of the electrode portions is larger than the wire width of the parallel portions. Therefore, the electrode portions are likely to block the electromagnetic wave transmitted from the in-vehicle sensor. However, according to the above configuration, since the electrode portions are disposed at positions without interfering with the electromagnetic wave transmitted from the in-vehicle sensor, it is possible to limit a decrease in detection accuracy of the object outside the vehicle by the electromagnetic wave due to the electromagnetic wave being blocked by the electrode portions.

In the sensor cover heat generating structure according to the aspect, the in-vehicle sensor may transmit an electromagnetic wave in a predetermined angular range, and the plurality of parallel portions extend in parallel to the angular range.

According to this configuration, when the electromagnetic wave is transmitted from the in-vehicle sensor within the predetermined angular range, the electromagnetic wave and the plurality of parallel portions are less likely to interfere with each other. Therefore, it is possible to limit a decrease in the detection accuracy of the object outside the vehicle by the electromagnetic wave due to the plurality of parallel portions.

### BRIEF DESCRIPTION OF THE DRAWINGS

The present invention will become more fully understood from the detailed description given hereinbelow and the accompanying drawing which is given by way of illustration only, and thus is not limitative of the present invention and wherein:

FIG. 1A is a schematic view illustrating an in-vehicle sensor, a case, and a sensor cover, and FIG. 1B is an enlarged cross-sectional view illustrating a portion surrounded by a two-dot chain line in the sensor cover of FIGS. 1A and 1B;

FIG. 2 is a schematic diagram illustrating a heater wire;

FIG. 3 is a schematic diagram illustrating a positional relationship of electrode portions and parallel portions with respect to an electromagnetic wave transmitted from an in-vehicle sensor; and

FIG. 4 is a schematic view illustrating another example of the sensor cover.

### DETAILED DESCRIPTION OF THE INVENTION

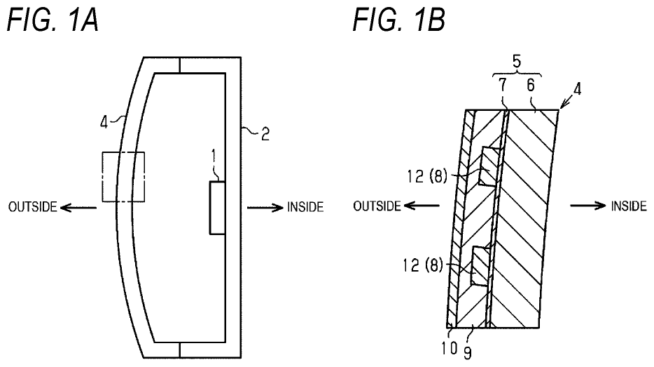

Hereinafter, an embodiment of a sensor cover heat generating structure will be described with reference to FIGS. 1A to 3.

FIG. 1A shows an in-vehicle sensor 1, a case 2, and a sensor cover 4. The in-vehicle sensor 1 transmits and receives an electromagnetic wave for detecting an object outside the vehicle, and may employ, for example, an infrared sensor. The infrared sensor transmits infrared rays as the electromagnetic wave to the outside of the vehicle (a left side in FIGS. 1A and 1B), receives infrared rays reflected by the object outside the vehicle, and detects the object outside the vehicle through the transmission and reception of the infrared rays.

The in-vehicle sensor 1 is housed in the case 2 mounted on the vehicle. The case 2 is open forward (leftward in FIGS. 1A and 1B) in the transmission direction of the electromagnetic wave in the in-vehicle sensor 1. The opening of the case 2 is attached with a sensor cover 4 for preventing the in-vehicle sensor 1 from being seen directly from the outside of the vehicle.

FIG. 1B is an enlarged cross-sectional view of a portion of the sensor cover 4 surrounded by a two-dot chain line in FIG. 1A. FIG. 1B illustrates a cover substrate 5 of the sensor cover 4 including a base layer 6 and a transparent film 7. The base layer 6 is formed of a transparent resin such as polyethylene terephthalate (PET). The transparent film 7 covers a surface of the base layer 6 opposite to the in-vehicle sensor 1 (a surface on the left side in FIG. 1B). The cover substrate 5 is located on a path of the electromagnetic wave transmitted and received by the in-vehicle sensor 1 (FIG. 1A). The cover substrate 5 of the sensor cover 4 is capable of transmitting the electromagnetic wave transmitted and received by the in-vehicle sensor 1.

The sensor cover 4 includes a heater wire 8, a protective layer 9, and an AR coating layer 10. The heater wire 8 is made of a metal such as copper, and generates heat when energized. The heater wire 8 is disposed on a surface of the cover substrate 5 (transparent film 7) opposite to the in-vehicle sensor 1. The protective layer 9 covers the heater wire 8 and the transparent film 7, and is formed of a transparent resin such as PET. The AR coating layer 10 is formed by an anti-reflection coating on a surface of the protective layer 9 opposite to the in-vehicle sensor 1. The protective layer 9 and the AR coating layer 10 of the sensor cover 4 are also capable of transmitting the electromagnetic wave transmitted and received by the in-vehicle sensor 1.

Next, the heater wire 8 will be described in detail.

The ice and snow adhering to the sensor cover 4 are melted through heat generated by energizing the heater wire 8. As a result, it is possible to prevent transmission of the electromagnetic wave to the sensor cover 4 from being hindered by the adhesion of ice and snow.

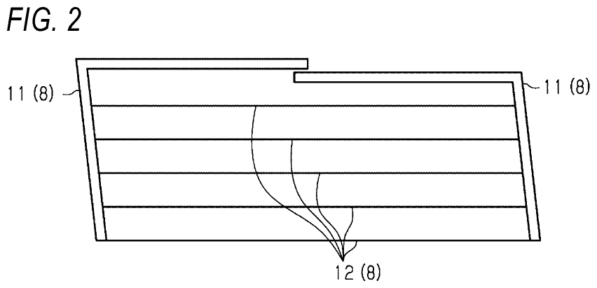

As shown in FIG. 2, the heater wire 8 includes two electrode portions 11 and plural parallel portions 12. The electrode portions 11 and the parallel portions 12 each have a thin film shape. The two electrode portions 11 have a predetermined length and are disposed at a distance from each other. The plural parallel portions 12 extend in parallel to each other so as to connect the two electrode portions 11. The electrode portions 11 have a wire width equal to or greater than a total value of wire widths of the plurality of parallel portions 12. When the electrode portions 11 are applied with a voltage, the electrode portions 11 and the plural parallel portions 12 of the heater wire 8 are energized, so that the heater wire 8 generates heat.

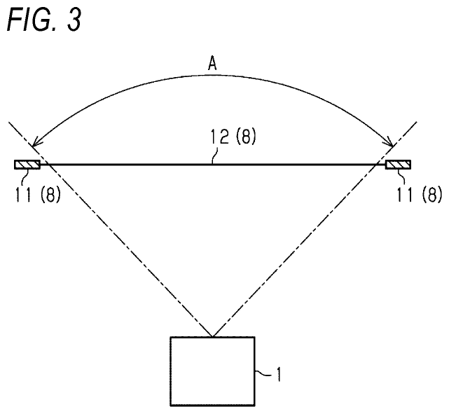

FIG. 3 illustrates a positional relationship of the electrode portions 11 and the parallel portions 12 with respect to the electromagnetic wave transmitted from the in-vehicle sensor 1. The in-vehicle sensor 1 transmits an electromagnetic wave in a predetermined angular range A. The angular range A extends to be substantially horizontal. The electrode portions 11 of the heater wire 8 are disposed at positions without interfering with the electromagnetic wave transmitted from the in-vehicle sensor 1, in other words, at positions without overlapping the angular range A. The plural parallel portions 12 of the heater wire 8 extend in parallel to the angular range A. In this example, the plural parallel portions 12 extend substantially in a horizontal direction.

The plural parallel portions 12 of the heater wire 8 have a wire width w set to a value less than a maximum value that can secure the transmittance of electromagnetic wave in the sensor cover 4. Such maximum value of the wire width w is, for example, 100 μm. The heater wire 8 including the electrode portions 11 and the plural parallel portions 12 is provided to the sensor cover 4 by a method capable of providing the heater wire 8 to the sensor cover 4 in a thin film shape, for example, by sputtering. The heater wire 8 may be provided to the sensor cover 4 by a method other than sputtering that is capable of providing the heater wire 8 to the sensor cover 4 in a thin film shape, for example, by dry plating such as vapor deposition, or by wet plating such as electroplating or electroless plating.

Next, an operation of the heat generating structure of the sensor cover 4 according to the present embodiment will be described.

The heat generation amount of the heater wire 8 is determined by a resistance value R of the entire heater wire 8, and the resistance value R is determined by a length L and a cross-sectional area S of the heater wire 8. When the heater wire 8 has a thin film shape, the cross-sectional area S is a product of the wire width w and the thickness t of the heater wire 8. In the plural parallel portions 12 of the heater wire 8, since the wire width w needs to be less than the maximum value described above, the thickness t needs to be adjusted to increase the cross-sectional area S for limiting the heat generation amount in the parallel portions 12 to a desired value.

However, when the thickness t is set to be large, for example, 3 μm or more, in a case where sputtering or the like is adopted as the method for providing the heater wire 8 including the electrode portions 11 and the plural parallel portions 12 to the sensor cover 4, the thickness t may be too large and the heater wire 8 may be peeled off. In this regard, in the heater wire 8, the plural parallel portions 12 are connected to the two electrode portions 11 so as to connect the two electrode portions 11 to each other. In this case, a total resistance value of the plural parallel portions 12 can be limited small even if the thickness t of each of the plural parallel portions 12 is small, which limits an increase in the cross-sectional area S of the parallel portions 12 and increases a resistance value of each of the parallel portions 12.

Therefore, it is not necessary to increase the thickness t of the parallel portions 12 in order to limit the heat generation amount (corresponding to the resistance value) of the heater wire 8 to a desired value. As a result, it is possible to adopt a method that cannot sufficiently reduced the thickness t of the heater wire 8, such as sputtering, as a method for providing the heater wire 8 to the sensor cover 4, so that limitation on the method for providing the heater wire 8 to the sensor cover 4 can be prevented.

In the heater wire 8, the electrode portions 11 have a wire width equal to or greater than the total value of the wire widths of the plural parallel portions 12. Thereby, a current density of the electrode portions 11 to which the plural parallel portions 12 are connected can be limited small. As a result, it is possible to limit an increase in heat generation amount of the electrode portions 11, thereby limiting occurrence of uneven heat generation in the heater wire 8 including the electrode portions 11 and the plural parallel portions 12 due to an increase in the heat generation amount of the electrode portions 11.

According to the present embodiment described in detail above, the following effects can be obtained.

(1) Limitation on the method for providing the heater wire 8 to the sensor cover 4 can be prevented.

(2) Uneven heat generation in the heater wire 8 can be limited.

(3) The wire width of the electrode portions 11 is larger than the wire width of the parallel portions 12. Therefore, the electrode portions 11 are likely to block the electromagnetic wave transmitted from the in-vehicle sensor 1. However, since the electrode portions 11 are disposed at positions without interfering with the electromagnetic wave transmitted from the in-vehicle sensor 1, it is possible to limit a decrease in detection accuracy of the object outside the vehicle by the electromagnetic wave due to the electromagnetic wave being blocked by the electrode portions 11.

(4) The in-vehicle sensor 1 transmits the electromagnetic wave in the predetermined angular range A. The plural parallel portions 12 extend in parallel to the angular range A. Therefore, when the electromagnetic wave is transmitted from the in-vehicle sensor 1 within the predetermined angular range A, the electromagnetic wave and the plurality of parallel portions 12 are less likely to interfere with each other. Therefore, it is possible to limit a decrease in the detection accuracy of the object outside the vehicle by the electromagnetic wave due to the plural parallel portions 12.

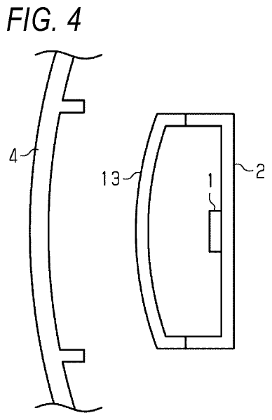

The above embodiment may be modified, for example, as follows. The above embodiment and the following modifications can be implemented in combination with each other within a technically consistent range.
The sensor cover 4 is exemplified as one attached to the case 2, but may also be provided separately from the case 2 as illustrated in FIG. 4. In this case, the case 2 is attached with a separate cover 13 for closing the opening thereof
The angular range A for transmitting the electromagnetic wave from the in-vehicle sensor 1 does not necessarily extend horizontally.
The two electrode portions 11 of the heater wire 8 may be disposed at positions interfering with the electromagnetic wave transmitted from the in-vehicle sensor 1, in other words, at positions overlapping the angular range A. In this case, the angular range A may be limited by adjusting the positions of the two electrode portions 11.
The heater wire 8 may be provided to the sensor cover 4 by dispensing or printing a metal paste.
The in-vehicle sensor 1 that transmits and receives the electromagnetic wave is exemplified by an infrared sensor, whereas the in-vehicle sensor 1 may also be a millimeter wave radar that transmits and receives a millimeter wave as the electromagnetic wave.

What is claimed is:

1. A sensor cover heat generating structure, applied to a sensor cover of an in-vehicle sensor that transmits and receives an electromagnetic wave for detecting an object outside a vehicle, the sensor cover being located in front of the in-vehicle sensor in a transmission direction of the electromagnetic wave, the sensor cover heat generating structure comprising:
a heater wire provided to the sensor cover, the heater wire being configured to generate heat when the heater wire is energized, wherein:
the heater wire includes two electrode portions and a plurality of parallel portions;
the two electrode portions have a predetermined length and are disposed at a distance from each other;
the plurality of parallel portions extend in parallel to each other so as to connect the two electrode portions; and
the electrode portions have a wire width equal to or greater than a total value of wire widths of the plurality of parallel portions.

2. The sensor cover heat generating structure according to claim 1, wherein
the electrode portions are disposed at positions without interfering with the electromagnetic wave transmitted from the in-vehicle sensor.

3. The sensor cover heat generating structure according to claim 1, wherein:
the in-vehicle sensor transmits an electromagnetic wave in a predetermined angular range; and
the plurality of parallel portions extend in parallel to the angular range.
